(19) United States
(12) Patent Application Publication
(10) Pub. No.: US 2025/0062298 A1
(43) Pub. Date: Feb. 20, 2025

(54) PACKAGE STRUCTURE AND METHOD FOR FORMING SAME

(71) Applicant: JCET Group Co., Ltd., Wuxi (CN)

(72) Inventors: Yaojian LIN, Wuxi (CN); Yao LI, Wuxi (CN); Danfeng YANG, Wuxi (CN); Lei LV, Wuxi (CN)

(73) Assignee: JCET Group Co., Ltd., Wuxi, JS (CN)

(21) Appl. No.: 18/792,364

(22) Filed: Aug. 1, 2024

(30) Foreign Application Priority Data
Aug. 16, 2023 (CN) 202311033856.4

(51) Int. Cl. H01L 25/16; H01L 21/48; H01L 21/56; H01L 23/00; H01L 23/31; H01L 23/36; H01L 23/538

(52) U.S. Cl. CPC H01L 25/16; H01L 23/538; H01L 24/13; H01L 21/4828; H01L 21/56; H01L 23/3107; H01L 23/36; H01L 24/16; H01L 24/32; H01L 24/48; H01L 24/73; H01L 2224/13082; H01L 2224/16245; H01L 2224/32245; H01L 2224/48248; H01L 2224/73207; H01L 2224/73253; H01L 2224/73265

(57) ABSTRACT

The present disclosure relates to a package structure and a method for forming the same. The package structure includes: a plurality of second interconnect metal traces and bonding pads in a same plane; a plurality of first surface metal bumps and first interconnect metal traces disposed on the first surfaces of the second interconnect metal traces; a plurality of passive devices correspondingly mounted on top surfaces of the first surface metal bumps; a first molding layer encapsulating the passive devices, the first surface metal bumps, and the first interconnect metal traces, and covering the first surfaces of the bonding pads; a dielectric layer covering the second surfaces of the second interconnect metal traces and a bottom surface of the first molding layer; a first chip having wire bonding pads; and metal wires electrically connecting the wire bonding pads to the second surfaces of the bonding pads.

### CROSS-REFERENCE TO RELATED APPLICATIONS

This application is based upon and claims priority to Chinese Patent Application No. 202311033856.4, filed on Aug. 16, 2023, the entire content of which is incorporated herein by reference for all purposes.

### TECHNICAL FIELD

The present disclosure relates to the technical field of semiconductor packaging, and in particular, relates to a package structure and a packaging method.

### BACKGROUND

Passive devices refer to electronic devices that do not contain an electronic source and cannot amplify or regulate current or signals. These electronic devices only participate in passive functions in basic circuit structures, such as transmitting and distributing electrical energy. The most common passive devices include resistors, capacitors, inductors, ceramic resonators, crystal oscillators, transformers, or the like. From the perspective of their operating characteristics, the passive devices do not consume electrical energy themselves or convert electrical energy into other forms of energy. The passive devices function normally in response to only an input signal, with no need of an external power supply.

In packaging of a semiconductor chip, it is common to package the semiconductor chip together with corresponding passive devices to implement specific functions. In current packaging of a semiconductor chip and passive devices, the passive devices are typically placed on the back face of the semiconductor chip. The semiconductor chip and the passive devices are electrically connected via an interconnect structure that extends through a through silicon via in the semiconductor chip. However, this packaging method limits the number of passive devices that can be included and involves a complex and costly silicon via process.

### SUMMARY

According to a first aspect of the present disclosure, a package structure is provided, which may include:
a plurality of second interconnect metal traces and bonding pads in a same plane, wherein the bonding pads are electrically connected to a portion of the plurality of second interconnect metal traces, and the plurality of second interconnect metal traces and the bonding pads comprise first surfaces and second surfaces that are opposite;
a plurality of first surface metal bumps and first interconnect metal traces disposed on the first surfaces of the plurality of second interconnect metal traces;
a plurality of passive devices correspondingly mounted on top surfaces of the plurality of first surface metal bumps, wherein the plurality of passive devices are correspondingly electrically connected to the first surface metal bumps and the first interconnect metal traces;
a first molding layer encapsulating the plurality of passive devices, the plurality of first surface metal bumps, and the first interconnect metal traces, and covering the first surfaces of the bonding pads;
a dielectric layer covering the second surfaces of the plurality of second interconnect metal traces and a bottom surface of the first molding layer, wherein openings exposing the second surfaces of the bonding pads are defined in the dielectric layer;
a first chip comprising a back face and a functional face that are opposite, wherein second bonding pads are arranged on the functional face of the first chip, and the back face of the first chip is mounted on a surface of the dielectric layer; and
metal wires electrically connecting the second bonding pads to the second surfaces of the bonding pads.

According to a second aspect of the present disclosure, a method for forming a package structure is provided, which may include:
providing a metal foil, wherein the metal foil comprises a first surface and a second surface that are opposite;
forming a plurality of first surface metal bumps and first interconnect metal traces on the first surface of the metal foil;
mounting a plurality of passive devices on top surfaces of the plurality of first surface metal bumps, wherein the plurality of passive devices are correspondingly electrically connected to the plurality of first surface metal bumps and the first interconnect metal traces;
forming a first molding layer, wherein the first molding layer encapsulates the plurality of passive devices, the plurality of first surface metal bumps, and the first interconnect metal traces, and covers the first surface of the metal foil;
etching the metal foil from the second surface of the metal foil to form a plurality of second interconnect metal traces and bonding pads that are correspondingly electrically connected to the plurality of first surface metal bumps and the first interconnect metal traces;
forming a dielectric layer covering the plurality of second interconnect metal traces and a bottom surface of the first molding layer, wherein openings exposing surfaces of the bonding pads are defined in the dielectric layer;
providing a first chip, wherein the first chip comprises a back face and a functional face that are opposite, second bonding pads being arranged on the functional face;
mounting the back face of the first chip on a surface of the dielectric layer; and
forming metal wires electrically connecting the second bonding pads to the bonding pads.

It is to be understood that the above general descriptions and detailed descriptions below are only exemplary and explanatory and not intended to limit the present disclosure.

### BRIEF DESCRIPTION OF THE DRAWINGS

The accompanying drawings, which are incorporated in and constitute a part of this specification, illustrate embodiments consistent with the present disclosure and, together with the description, serve to explain the principles of the present disclosure.

FIG. 1 is a schematic structural diagram of a process for providing a metal foil in forming a package structure according to some embodiments of the present disclosure.

FIG. 2 is a schematic structural diagram of a process for correspondingly mounting a plurality of passive devices on top surfaces of a plurality of surface metal bumps in forming the package structure according to some embodiments of the present disclosure.

FIG. 3 is a schematic structural diagram of a process for forming a first molding layer encapsulating the passive devices, the first surface metal bumps, and first interconnect metal traces and covering a first surface of the metal foil in forming the package structure according to some embodiments of the present disclosure.

FIG. 4 is a schematic structural diagram of a process for etching the metal foil in forming the package structure according to some embodiments of the present disclosure.

FIG. 5 is a schematic structural diagram of a process for forming a dielectric layer covering second interconnect metal traces and a bottom surface of the first molding layer in forming the package structure according to some embodiments of the present disclosure.

FIG. 6 is a schematic structural diagram of a process for providing a first chip in forming the package structure according to some embodiments of the present disclosure.

FIG. 7 is a schematic structural diagram of a process for forming metal wires electrically connecting wire bonding pads to bonding pads in forming the package structure according to some embodiments of the present disclosure.

FIG. 8 is a schematic structural diagram of a process for forming a second molding layer encapsulating the first chip, the metal wires, and the wire bonding pads in forming the package structure according to some embodiments of the present disclosure.

FIG. 9 is a schematic structural diagram of a process for thinning the second molding layer to expose top surfaces of metal pillars and forming solder balls on the top surfaces of the metal pillars in forming the package structure according to some embodiments of the present disclosure.

FIG. 10 is a schematic structural diagram of a process for forming a package structure according to some embodiments of the present disclosure.

FIG. 11 is a schematic structural diagram of a process for forming a package structure according to some embodiments of the present disclosure.

FIG. 12 is a schematic structural diagram of a process for forming a package structure according to some embodiments of the present disclosure.

FIG. 13 is a schematic structural diagram of a process for forming a package structure according to some embodiments of the present disclosure.

FIG. 14 is a schematic structural diagram of a process for forming a package structure according to some embodiments of the present disclosure.

FIG. 15 is a schematic structural diagram of a process for forming a package structure according to some embodiments of the present disclosure.

### DETAILED DESCRIPTION

The specific embodiments of the present disclosure are described in detail hereinafter with reference to the accompanying drawings. In the description of the embodiments of the present disclosure, for ease of illustration, the schematic structural views are not partially enlarged according to a typical scale, and the schematic views are given for exemplary purpose only, which do not limit the protection scope of the present disclosure. In addition, in practice, a three-dimension spatial size in terms of length, width, and depth needs to be included.

Some embodiments of the present disclosure provide a method for forming a package structure. Hereinafter, the method is described with reference to the accompanying drawings.

Referring to FIG. 1, a metal foil 100 is provided. The metal foil 100 includes a first surface and a second surface that are opposite. A plurality of first surface metal bumps 101 and first interconnect metal traces (not illustrated) are formed on the first surface of the metal foil 100. The metal foil 100 is used for subsequently forming corresponding second interconnect metal traces and pads (for example, bonding pads). In some embodiments, the metal foils 100 may also serve as a carrier for subsequent processes.

For better description, “wire bonding pads 303” or “wire bonding pads” is used hereafter to refer to “second bonding pads.”

The metal foil 100 may be made of a conductive metal plate or metal frame. In some embodiments, the metal foil 100 may be made of one or more of copper, aluminum, nickel, tin, tungsten, platinum, titanium, chromium, tantalum, gold, or silver, or any alloy thereof.

In some embodiments, the metal foil 100 has a thickness of 20 to 400 μm, in a specific embodiment, for example, 150 μm.

In some embodiments, the method further includes: providing a carrier plate (not illustrated), wherein the metal foil 100 is disposed on a surface of the carrier plate, and in a specific embodiment, the metal foil 100 may be attached to the surface of the carrier plate via an adhesive layer; and removing the carrier plate subsequently prior to etching the second surface of the metal foil and upon forming a first molding layer. The carrier plate may better support for the subsequent processes. In some embodiments, the carrier plate may be a glass carrier plate, a ceramic carrier plate, a resin carrier plate, a silicon carrier plate; and the carrier plate may be in the shape of a strip, a rectangular bar, or a circle.

The metal foil 100 may include a first surface and a second surface that are opposite. According to the number of pins of passive devices to be subsequently mounted and the circuitry design, a plurality of first surface metal bumps 101 and first interconnect metal traces (not illustrated) are formed on the first surface of the metal foil 100. In some embodiments, a portion of the first surface metal bumps 101 are discrete, and a portion of the first surface metal bumps 101 are connected via the first interconnect metal traces.

The passive devices are subsequently mounted on and electrically connected to top surfaces of the first surface metal bumps 101, and the first surface metal bumps 101 are further configured to raise the subsequently mounted passive devices for ease of the progress of the subsequent processes of mounting the passive devices and forming the first molding layer. It should be noted that the top surfaces of the first surface metal bumps 101 (and second metal bumps, a third metal bump, fourth metal bumps, and fifth metal bumps in subsequent other embodiments) refer to surfaces thereof that are not in contact with the metal foil 100 or surfaces of subsequently formed second interconnect metal traces. Correspondingly, bottom surfaces of the first surface metal bumps 101 (and the second metal bumps, the third metal bump, the fourth metal bumps, and the fifth metal bumps in subsequent other embodiments) refer to surfaces that are in contact with the metal foil 100 or the surfaces of the subsequently formed second interconnect metal traces.

In some embodiments, the first metal surface bumps 101 and the first interconnect metal traces may be made of one or more of Al, Cu, Ag, Au, Pt, Ni, Ti, TiN, TaN, Ta, TaC, W, or WN, or any alloy thereof.

In some embodiments, the first surface metal bumps 101 and the first interconnect metal traces are formed by a precision stamping process, an electroplating process, or a post-mask etching process.

In some embodiments, the method further includes: forming second metal bumps 102 on the first surface of the metal foil 100. The second metal bumps 102 are disposed outside the first surface metal bumps 101.

Bottom surfaces of the second metal bumps 102 are electrically connected to subsequently formed bonding pads. During subsequently forming metal wires on the bonding pads by a wire bonding process, the second metal bumps 102 are configured to support the bonding pads, such that the bonding pads are prevented from deformation or displacement, reliability of the package structure is improved, and heat dissipation is enhanced. In some embodiments, subsequently second heat sinks may also be mounted on top surfaces of the second metal bumps 102, to further improve heat dissipation performance and enhance rigidity at corresponding positions to balance or the package structure or prevent warpage of the package structure. In some embodiments, subsequently sixth metal bumps may also be mounted on the top surfaces of the second metal bumps 102 to lead electrical connection points of the package structure to a side, far away from the metal traces, of the first molding layer.

The second metal bumps 102 and the first surface metal bumps 101 may be made of the same material and may have the same height, and the second metal bumps 102, the first surface metal bumps 101, and the first interconnect metal traces are simultaneously formed in the same process.

The second metal bumps 102 are disposed outside the first surface metal bumps 101. Specifically, the second metal bumps 102 are disposed on peripheries of or in the vicinity of the first surface metal bumps 101, and correspondingly, the bonding pads formed upon subsequently etching the metal foil are also disposed on the peripheries of or around the first surface metal bumps 101, such that subsequent formation of the metal wires electrically connecting the wire bonding pads on the first chip to the bonding pads is facilitated.

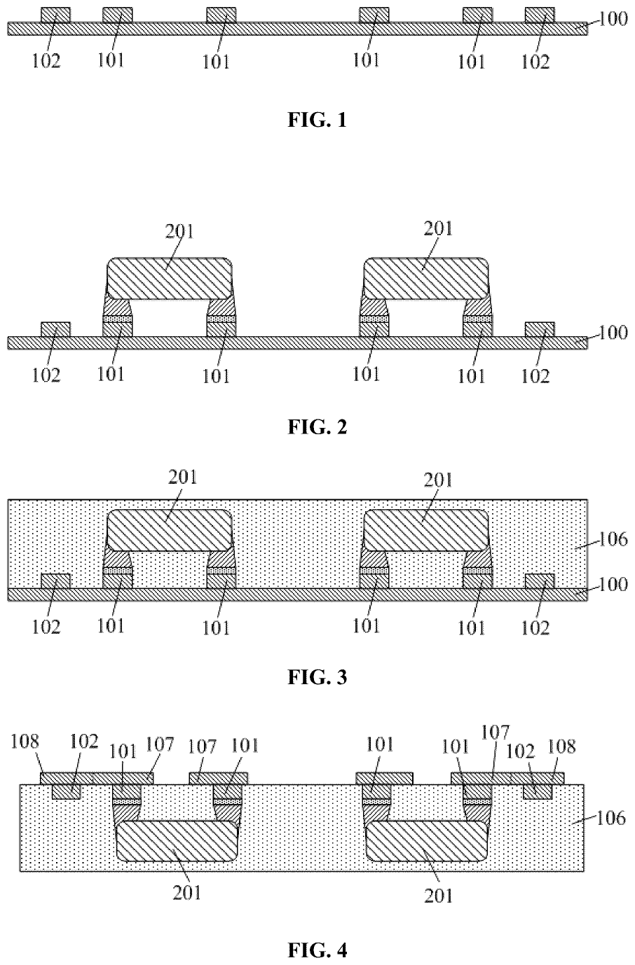

Referring to FIG. 2, a plurality of passive devices 201 are correspondingly mounted on the top surfaces of the first surface metal bumps 101. The passive devices 201 are correspondingly electrically connected to the first surface metal bumps 101 and the first interconnect metal traces.

The number of mounted passive devices 201 may be two or greater than two. Each of the passive devices 201 may be one or more of a resistor, a capacitor, or an inductor. The passive device 201 may be one or more of a ceramic resonator, a crystal oscillator, a transformer, a converter, a tapered transformer, a matching network, a resonator, a filter, a mixer, a switch, an electrical bridge, or an antenna.

The passive device 201 has pins. In some embodiments, the passive devices 201 are mounted on the top surfaces of the first surface metal bumps 101 and are electrically connected via a metal bonding assist layer. An area of the metal bonding assist layer may be equal to or not equal to an area of the top surfaces of the first surface metal bumps 101. In some embodiments, the metal bonding assist layer includes a solder layer, and the metal bonding assist layer is made of one or more of tin, tin-silver, tin-lead, silver-copper, tin-silver-copper, tin-silver-zinc, tin-zinc, tin-bismuth-indium, tin-indium, tin-gold, tin-copper, tin-zinc-indium, or tin-silver-antimony. The metal bonding assist layer may also be made of silver, nickel-gold, or nickel-palladium-gold.

Referring to FIG. 3, a first molding layer 106 encapsulating the passive devices 201, the first surface metal bumps 101, and the first interconnect metal traces, and covering the first surface of the metal foil 100 is formed.

The first molding layer 106 is configured to protect and seal the passive devices 201. The first molding layer 106 further encapsulates the second metal bumps 102.

In some embodiments, the first molding layer 106 may be made of filler-containing epoxy resin, polyimide resin, benzocyclobutene resin, or polybenzoxazole resin; or may be polybutylene terephthalate, polycarbonate, polyethylene terephthalate, polyethylene, polypropylene, polyolefin, polyurethane, polyolefin, polyethersulfone, polyamide, polyurethane, ethylene-vinyl acetate copolymer, or polyvinyl alcohol. The first molding layer 106 may be formed by an injection molding processing or a rotational molding process.

Referring to FIG. 4, the metal foil 100 is etched from the second surface of the metal foil 100 (referring to FIG. 3) to form second interconnect metal traces 107 and bonding pads 108 that are correspondingly electrically connected to the first surface metal bumps 101 and the first interconnect metal traces. The bonding pads 108 are disposed outside the second interconnect metal traces 107.

The second interconnect metal traces 107 are formed on the bottom surfaces of the first surface metal bumps 101, the first interconnect metal traces, and the first molding layer 106, and the bonding pads 108 are formed on the bottom surfaces of the second metal bumps 102 and the first molding layer 106. The bottom surfaces of the first surface metal bumps 101, the second metal bumps 102, and the first molding layer 106 are the surfaces thereof that are in contact with the metal foil 100.

The formed second interconnect metal traces 107 are configured to achieve interconnection between the passive devices 201. In some embodiments, a portion of the second interconnect metal traces 107 are further configured to electrically connect the bonding pads 108 to at least a portion of the first surface metal bumps 101. In some other embodiments, the second interconnect metal traces 107 are further configured to electrically connect other devices (for example, a second chip) mounted on the first surface of the metal foil to the passive device 201 or to the bonding pads 108.

A first chip is subsequently mounted over surfaces, away from the first surface metal bumps 101, of the formed second interconnect metal trances 107, the formed bonding pads 108 are disposed outside (on the peripheries or in the vicinity of) the second interconnect metal traces 107, such that electrical connections of wire bonding pads on the subsequently mounted first chip to the bonding pads 108 via metal traces formed by a wire bonding process are facilitated.

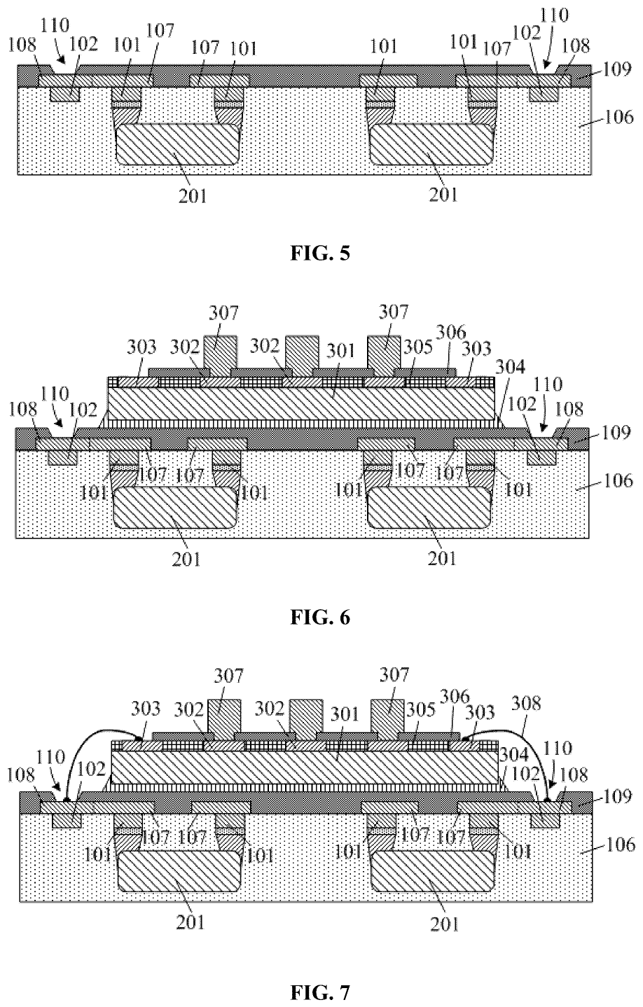

Referring to FIG. 5, a dielectric layer 109 covering the second interconnect metal traces 107 and a bottom surface of the first molding layer 106 is formed, wherein openings 110 exposing surfaces of the bonding pads 108 are defined in the dielectric layer 109.

The bottom surface of the first molding layer 106 is a surface that is in contact with the second interconnect metal traces 107. The dielectric layer 109 covers the second interconnect metal traces 107, which provides a flat surface for subsequently mounting the first chip. The openings 110 exposing the surfaces of the bonding pads 108 are defined in the dielectric layer 109, such that subsequent formation of metal wires electrically connecting the wire bonding pads on the first chip to the bonding pads 108 is facilitated.

In some embodiments, the dielectric layer 109 may be made of a filler-containing polymer, specifically including epoxy resin, polyimide resin, benzocyclobutene resin, or polybenzoxazole resin. In some other embodiments, the filler of the dielectric layer 109 may be one or more of silicon oxide, silicon nitride, silicon oxynitride, or silicon carbonitride.

Referring to FIG. 6, a first chip 301 is provided. The first chip 301 includes a back face and a functional face that are opposite. Wire bonding pads 303 are arranged on the functional face, and the back face of the first chip 301 is mounted on the surface of the dielectric layer 109.

The first chip 301 includes the back face and the functional face that are opposite. The back face of the first chip 301 is mounted on the surface of the dielectric layer 109, and a plurality of external pads 302 are arranged on the functional face of the first chip 301. In the embodiments, a portion of the external pads are used as the wire bonding pads 303. In some embodiments, via a top insulating layer 305, the external pads 302 are isolated from each other and the external pads 302 are isolated from the wire bonding pads 303.

The first chip 301 further includes external protrusions that protrude from a surface of the functional face and are electrically connected to the external pads 302. In some embodiments, the external protrusions include metal pillars 307 and solder balls 309 subsequently formed on surfaces of the metal pillars 307 (referring to FIG. 9). In some embodiments, passivation layers 306 disposed on a surface of the top insulating layer 305 are further formed on the functional face of the first chip 301, and first openings correspondingly exposing surfaces of the external pads 302 and second openings correspondingly exposing the wire bonding pads 303 are defined in the passivation layers 306. The metal pillars 307 are disposed in the first openings and surfaces of a portion of the passivation layers 306 outside the first openings.

In some embodiments, the external pads 302 and the wire bonding pads 303 are made of one or more of aluminum, nickel, tin, tungsten, platinum, copper, titanium, chromium, tantalum, gold, or silver; the metal pillars 307 is made of one or more of aluminum, nickel, tin, tungsten, platinum, copper, titanium, chromium, tantalum, gold, or silver; and the solder balls 309 are made of one or more of tin, tin-silver, tin-lead, tin-silver-copper, tin-silver-zinc, tin-zinc, tin-bismuth-indium, tin-indium, tin-gold, tin-copper, tin-zinc-indium, or tin-silver-antimony.

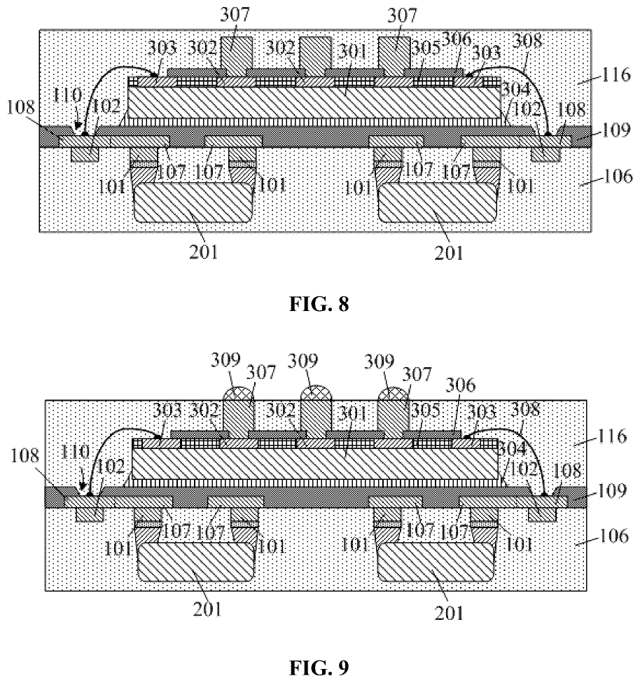

Referring to FIG. 7, metal wires 308 electrically connecting the wire bonding pads 303 to the bonding pads 108 are formed.

The metal wires 308 may be made of one or more gold, aluminum, copper, silver, nickel, or palladium, or any alloy thereof. The metal wires 308 may also be formed by a wire bonding process.

In some embodiments, referring to FIG. 8, the method further includes: forming a second molding layer 116, wherein the second molding layer 116 encapsulates the first chip 301, the metal wires 308, and the wire bonding pads 303.

The second molding layer 116 is configured to seal and protect the first chip 301. The second molding layer 116 further encapsulates the metal pillars 307.

In some embodiments, the second molding layer 116 may be made of filler-containing epoxy resin, polyimide resin, benzocyclobutene resin, or polybenzoxazole resin; or may be polybutylene terephthalate, polycarbonate, polyethylene terephthalate, polyethylene, polypropylene, polyolefin, polyurethane, polyolefin, polyethersulfone, polyamide, polyurethane, ethylene-vinyl acetate copolymer, or polyvinyl alcohol. The second molding layer 116 may be formed by an injection molding processing or a rotational molding process.

In some embodiments, referring to FIG. 9, the method further includes: thinning the second molding layer 116 to expose the top surfaces of the metal pillars 307; and forming the solder balls 309 on the top surfaces of the metal pillars 307.

The thinning may be achieved by a chemical mechanical polishing (CMP) process.

In the method for forming the package structure according to the above embodiments of the present disclosure, the passive devices are firstly mounted on the top surfaces of the first surface metal bumps on the first surface of the metal foil, and then the first molding layer encapsulating the passive devices, the first surface metal bumps, and the first interconnect metal traces, and covering the first surface of the metal foil is formed; the metal foil is etched from the second surface of the metal foil to form the second interconnect metal traces and the bonding pads that are correspondingly electrically connected to the first surface metal bumps and the first interconnect metal traces; and afterwards, the back face of the first chip is mounted on the surface of the dielectric layer, and the metal wires electrically connecting the wire bonding pads to the bonding pads are formed. When mounting the passive devices, the number of passive devices in the package is increased since the passive devices are not limited by the area of the back face of the first chip. Moreover, the passive devices are electrically connected to the first chip via the metal traces and the metal wires. The formation process of the metal traces and the metal wires is simpler and less costly compared to the silicon via process.

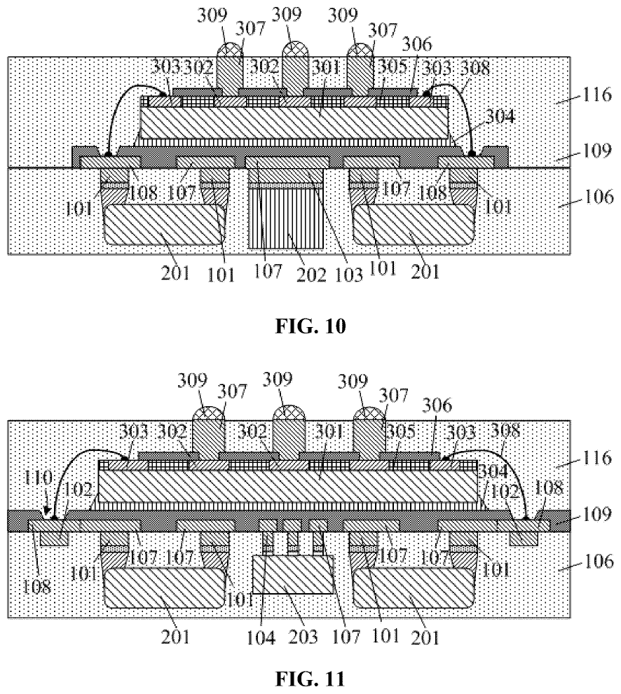

Some embodiments of the present disclosure further provide a method for forming a package structure. Referring to FIG. 10, different from the above embodiments (the embodiments as illustrated in FIG. 1 to FIG. 9), in the embodiments herein, no second metal bumps are formed on the first surface of the metal foil, and the bonding pads 108 (formed upon etching the metal foil) are directly formed on the bottom surfaces of a portion of the first surface metal bumps 101. That is, the first surface metal bumps 101 are not only configured to be electrically connected to pins of the passive devices 201 and the bonding pads, but also configured to support the bonding pads, to improve stability of the package structure. In addition, there is no need to deploy the bonding pads outside the first surface metal bumps 101 or metal bumps to support the bonding pads, such that the package structure has a smaller volume and a simpler structure. In addition, different from the above embodiments, in the embodiments herein, a third metal bump 103 is formed on the first surface of the metal foil (a portion of the second interconnect metal traces 107 formed upon etching the metal foil), wherein the third metal bump 103 is disposed between the first surface metal bumps 101 and opposite to a mount position of the first chip 301; a portion of the second interconnect metal bumps 107 formed upon etching the metal foil are electrically connected to the third metal bump 103; a first heat sink 202 is formed, wherein the first heat sink 202 is mounted on a top surface of the third metal bump 103; and the first molding layer 106 further covers a sidewall surface of the third metal bump 103 and at least covers a sidewall surface of the first heat sink 202.

The first heat sink 202 is configured to improve heat dissipation performance of the back face of the first chip 301, and enhance rigidity of at the corresponding position of the package structure to balance the package structure or prevent warpage of the package structure. The first heat sink 202 is made of a material with high thermal conductivity coefficient and low thermal expansion coefficient. A thermal conductivity coefficient of the first heat sink 202 is greater than or equal to 50 W/m·K, and a thermal expansion coefficient of the first heat sink 202 is less than or equal to 17 ppm/C. In a specific embodiment, the thermal expansion coefficient of the first heat sink 202 is less than or equal to 7 ppm/C, such that the first heat sink 202 better enhances the rigidity at the corresponding position of the package structure while better improving the heat dissipation performance of the back face of the first chip 301, and hence the package structure is better balanced, and the warpage of the package structure is better prevented. In some embodiments, the first heat sink 202 may be made of copper, aluminum, gold, nickel, steel, or stainless steel, or a carbon-containing material (for example, graphite, graphene, or carbon nanomaterial), or Si.

In some embodiments, the first heat sink 202 may be mounted while the passive devices 201 are being mounted, or may be mounted upon or prior to mounting of the passive devices 201. The first heat sink 202 is mounted on the top surface of the third metal bump 103 via a thermal adhesive or sintered silver.

In some embodiments, the first molding layer 106 may wrap the sidewall and bottom surfaces of the first heat sink 202. In some embodiments, the first molding layer 106 may only wrap the sidewall surface of the first heat sink 202, while exposing the top surface of the first heat sink 202.

Some embodiments of the present disclosure further provide a method for forming a package structure. Referring to FIG. 11, different from the above embodiments (the embodiments illustrated in FIG. 1 to FIG. 10), in the embodiments herein, a plurality of fourth metal bumps 104 are formed in the first surface of the metal foil (a portion of the second interconnect metal traces 107 formed upon etching the metal foil); the portion of the second interconnect metal traces 107 formed upon etching the metal foil are electrically connected to the fourth metal bumps 104; a second chip 203 is provided, wherein the second chip 203 is flip-mounted on top surfaces of the fourth metal bumps 104, and the second chip 203 is electrically connected to the fourth metal bumps 104; and the first molding layer 106 further covers sidewall surfaces of the fourth metal bumps 104 and a surface of the second chip 203.

The second chip 203 may be electrically connected to the passive devices 201 via the fourth metal bumps 104 and a portion of the second interconnect metal traces 107, such that functionality of the package structure is enhanced.

In some embodiments, the second chip 203 may be one of a signal processing chip, a logic control chip, a memory chip, a sensor chip, a power supply chip, or a radio frequency chip.

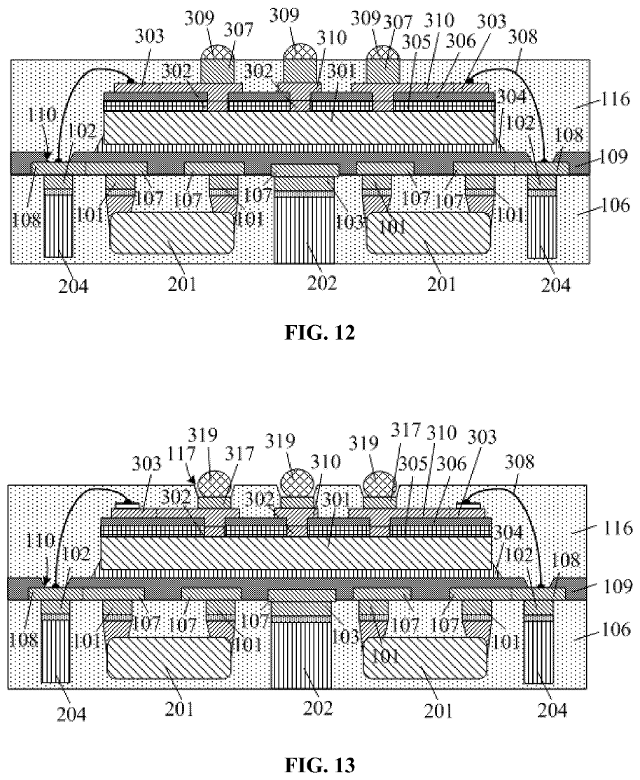

Some embodiments of the present disclosure provide a method forming a package structure. Referring to FIG. 12, different from the above embodiments (the embodiments as illustrated in FIG. 1 to FIG. 11), in the embodiments herein, second heat sinks 204 are provided, wherein the second heat sinks 204 are mounted on the top surfaces of the second metal bumps 102, the first molding layer 106 at least further covers sidewall surfaces of the second heat sinks 204, and the external protrusions (the metal pillars 307) on the first chip 301 are electrically connected to a portion of the external pads 302 via redistribution layers 310 to achieve better deployment of the external protrusions; and a portion of the redistribution layers 310 are used as the wire bonding pads 303 of the first chip 301.

The second heat sinks 204 are mounted on the top surfaces of the second metal bumps 102, and are configured to improve heat dissipation performance of the package structure, and enhance rigidity of at the corresponding position of the package structure to balance the package structure or prevent warpage of the package structure. The second heat sink 204 is made of a material with high thermal conductivity coefficient and low thermal expansion coefficient. A thermal conductivity coefficient of the second heat sinks 204 is greater than or equal to 50 W/m·K, and a thermal expansion coefficient of the second heat sinks 204 is less than or equal to 17 ppm/C. In a specific embodiment, the thermal expansion coefficient of the first heat sink 204 is less than or equal to 7 ppm/C, such that the second heat sinks 204 better enhance the rigidity at the corresponding position of the package structure while better improving the heat dissipation performance of the package structure, and hence the package structure is better balanced, and the warpage of the package structure is better prevented. In some embodiments, the second heat sinks 204 may be made of copper, aluminum, gold, nickel, steel, or stainless steel, or a carbon-containing material (for example, graphite, graphene, or carbon nanomaterial), or Si.

In some embodiments, the second heat sinks 204 may be mounted while the first heat sink is being mounted. In some embodiments, the second heat sinks 204 may be mounted while the passive devices 201 are being mounted, or may be mounted upon or prior to mounting of the passive devices 201. The second heat sinks 204 are mounted on the top surfaces of the second metal bumps 102 via a thermal adhesive or sintered silver.

In some embodiments, the first molding layer 106 may wrap the sidewall and the bottom surfaces of the second heat sinks 204. In some embodiments, the first molding layer 106 may only wrap the sidewall surfaces of the second heat sinks 204, while exposing the top surfaces of the second heat sinks 204.

Some embodiments of the present disclosure further provide a method for forming a package structure. Referring to FIG. 13, different from the above embodiments (the embodiments illustrated in FIG. 1 to FIG. 12), in the embodiments herein, the external protrusions on the functional face of the first chip are solder balls or metal core balls 319, wherein the solder balls or metal core balls 319 may be formed on surfaces of the redistribution layers 310 (or may be formed on the surfaces of the external pads 302 in other embodiments), and an under-ball metal layer 317 may also be disposed between the solder balls or metal core balls 319 and the redistribution layers 310 (or the external pads 302); a plurality of discrete openings 117 exposing the surfaces of the redistribution layers 310 are defined in the second molding layer, wherein the external protrusions (the solder balls or metal core bumps 319) are formed at the corresponding openings 117, and the discrete openings 117 may be formed by laser etching or thinning the second molding layer 116.

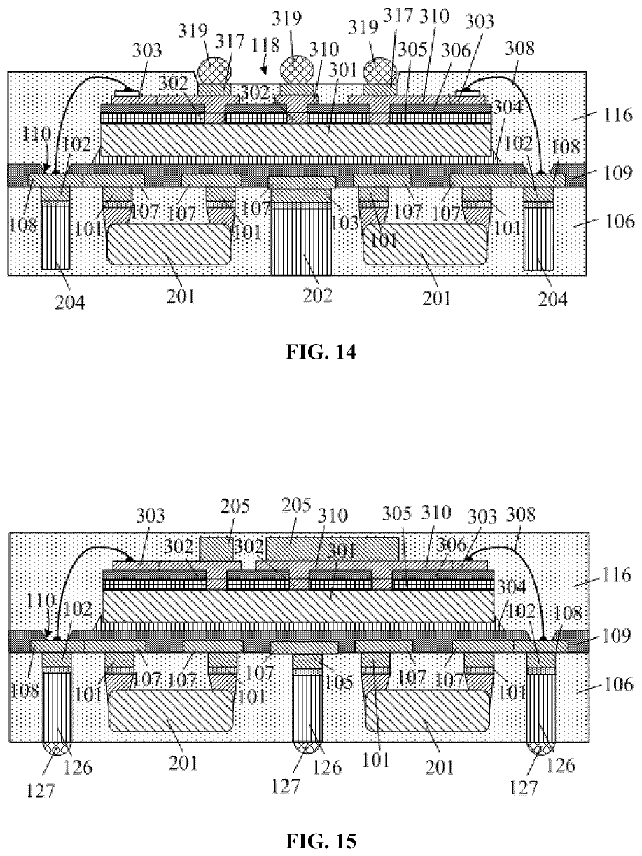

Some embodiments of the present disclosure further provide a method for forming a package structure. Referring to FIG. 14, different from the above embodiments (the embodiments illustrated in FIG. 1 to FIG. 13), in the embodiments herein, the external protrusions on the functional face of the first chip are solder balls or metal core balls 319, wherein the solder balls or metal core balls 319 may be formed on surfaces of the redistribution layers 310 (or may be formed on the surfaces of the external pads 302 in other embodiments), and an under-ball metal layer 317 may also be disposed between the solder balls or metal core balls 319 and the redistribution layers 310 (or the external pads 302); an opening 118 correspondingly exposing the surfaces of the redistribution layers 310 is defined in the second molding layer, wherein the external protrusions (the solder balls or metal core bumps 319) are formed at the opening 118 and are electrically connected to the corresponding redistribution layers 310, and the opening 118 may be formed by laser etching or thinning the second molding layer 116 or may be directly formed during forming the second molding layer 116 by a film-assisted molding process.

Some embodiments of the present disclosure further provide a method for forming a package structure. Referring to FIG. 15, different from the above embodiments (the embodiments illustrated in FIG. 1 to FIG. 14), in the embodiments herein, a plurality of external pads 302 are arranged on the functional face of the first chip 301; the first chip 301 further includes third heat sinks 205 that protrude from a surface of the functional face and are electrically connected to the external pads 302, wherein in some embodiment, the third heat sinks 205 may be directly electrically connected to the external pads 302 or electrically connected to the external pads 302 via the redistribution layers 310; and the method further includes: forming a plurality of discrete fifth metal bumps 105 on the first surface of the metal foil (a portion of the second interconnect metal traces 107 formed upon etching the metal foil), wherein the portion of the second interconnect metal traces 107 formed upon etching the metal foil are electrically connected to the fifth metal bumps 105; providing a plurality of sixth metal bumps 126, wherein the sixth metal bumps 126 are respectively mounted on top surfaces of the second metal bumps 102 and the fifth metal bumps 105, and the first molding layer 106 further covers sidewall surfaces of the sixth metal bumps 126 and exposes top surfaces of the sixth metal bumps 126; and forming solder balls 127 on the top surfaces of the sixth metal bumps 126.

The first heat sinks 205 are configured to improve heat dissipation performance of the front face (the functional face) of the first chip 301, and enhance rigidity of at the corresponding position of the package structure to balance the package structure or prevent warpage of the package structure. The third heat sinks 205 are made of a material with high thermal conductivity coefficient and low thermal expansion coefficient. A thermal conductivity coefficient of the third heat sinks 205 is greater than or equal to 50 W/m·K, and a thermal expansion coefficient of the third heat sinks 205 is less than or equal to 17 ppm/C. In a specific embodiment, the thermal expansion coefficient of the third heat sinks 205 is less than or equal to 7 ppm/C, such that the third heat sinks 205 better enhances the rigidity at the corresponding position of the package structure while better improving the heat dissipation performance of the back face of the first chip 301, and hence the package structure is better balanced, and the warpage of the package structure is better prevented. In some embodiments, the third heat sinks 205 may be made of copper, aluminum, gold, nickel, steel, or stainless steel, or a carbon-containing material (for example, graphite, graphene, or carbon nanomaterial), or Si.

In addition to supporting the bonding pads 108 and balancing warpage of the package structure, the second metal bumps 102 are further configured to be electrically connected to the sixth metal bumps 126 to lead external electrical connection points (the solder balls 127) of the package structure to the surface, away from the first chip 301, of the first molding layer 106.

Some embodiments of the present disclosure provide a package structure. Referring to FIG. 9, the package structure includes:
a plurality of second interconnect metal traces 107 and bonding pads 108 in a same plane, wherein the bonding pads 108 are disposed outside the second interconnect metal traces 107 and are electrically connected to a portion of the second interconnect metal traces 107, and the second interconnect metal traces 107 and the bonding pads 108 include first surfaces and second surfaces that are opposite;
a plurality of first surface metal bumps 101 and first interconnect metal traces (not illustrated) disposed on the first surfaces of the second interconnect metal traces 107;
a plurality of passive devices 201 correspondingly mounted on top surfaces of the first surface metal bumps 101, wherein the passive devices 201 are correspondingly electrically connected to the first surface metal bumps 101 and the first interconnect metal traces;
a first molding layer 106 encapsulating the passive devices 201, the first surface metal bumps 101, and the first interconnect metal traces, and covering the first surfaces of the bonding pads 108;
a dielectric layer 109 covering the second surfaces of the second interconnect metal traces 107 and a bottom surface of the first molding layer 106, wherein openings 110 exposing the second surfaces of the bonding pads 108 are defined in the dielectric layer 109;
a first chip 301, wherein the first chip 301 includes a back face and a functional face that are opposite, wire bonding pads 303 being arranged on the functional face of the first chip 301, the back face of the first chip 301 being mounted on a surface of the dielectric layer 109; and
metal wires 308 electrically connecting the wire bonding pads 303 to the second surfaces of the bonding pads 108.

In some embodiments, a portion of the first surface metal bumps 101 are discrete, and a portion of the first surface metal bumps 101 are connected via the first interconnect metal traces.

In some embodiments, still referring to FIG. 9, the bonding pads 108 are disposed outside the first surface metal bumps 101; and the package structure further includes: a plurality of second metal bumps 102 on the first surfaces of the bonding pads 108, wherein the second metal bumps 102 are disposed outside the first surface metal bumps 101, the bonding pads 108 are correspondingly electrically connected to the first surface metal bumps 101 and the first interconnect metal traces via a portion of the second interconnect metal traces 107, and the first molding layer 106 at least further covers sidewall surfaces of the second metal bumps 102.

In some embodiments, referring to FIG. 10, the bonding pads 108 are disposed on bottom surfaces of a portion of the first surface metal bumps 101.

In some embodiments, referring to FIG. 10, the package structure further includes a third metal bump 103 disposed on the first surfaces of a portion of the second interconnect metal traces 107; and a first heat sink 202, wherein the first heat sink 202 is mounted on a top surface of the third metal bump 103, and the first molding layer 106 further covers a sidewall surface of the third metal bump 103 and at least covers a sidewall surface of the first heat sink 202.

In some embodiments, the third metal bump 103 is disposed between the first surface metal bumps 101, and is opposite to a mount position of the first chip 301. Specifically, the third metal bump 103 may be disposed under a middle region of the mount position of the first chip 301.

In some embodiments, referring to FIG. 12 or FIG. 13, in a case that second metal bumps 102 are formed on the first surfaces of the bonding pads 108, the package structure further includes second heat sinks 204, wherein the second heat sinks 204 are mounted on top surfaces of the second metal bumps 102, and the first molding layer 106 at least further covers sidewall surfaces of the second heat sinks 204.

In some embodiments, referring to FIG. 11, the package structure further includes: a plurality of discrete fourth metal bumps 104 disposed on the first surfaces of the second interconnect metal traces 107; and a second chip 203, wherein the second chip 203 is flip-mounted on top surfaces of the fourth metal bumps 104, and the second chip 203 is electrically connected to the fourth metal bumps 104; wherein the first molding layer 106 further covers sidewall surfaces of the fourth metal bumps 104 and a surface of the second chip 203.

A plurality of external pads 302 are arranged on the functional face of the first chip 301; and the first chip 301 further includes external protrusions that protrude from a surface of the functional face and are electrically connected to the external pads 302.

In some embodiments, referring to FIG. 9, FIG. 10, FIG. 11, or FIG. 12, the external protrusions include metal pillars 307 and solder balls 309 disposed on top surfaces of the metal pillars 307. In some other embodiments, referring to FIG. 13 or FIG. 14, the external protrusions are solder balls or metal core balls 319.

In some embodiments, referring to FIG. 9, FIG. 10, and FIG. 11, the external protrusions are directly electrically bonded to a portion of the external pads 302. In some other embodiments, referring to FIG. 12, FIG. 13, and FIG. 14, the external protrusions are electrically connected to a portion of the external pads 302 via distribution layers 310.

In some embodiments, referring to FIG. 9, FIG. 10, and FIG. 11, a portion of the external protrusions are directly used as the wire bonding pads 303. In some embodiments, referring to FIG. 12, FIG. 13, FIG. 14, and FIG. 15, a portion of the redistribution layers are used as the wire bonding pads 308.

In some embodiments, referring to FIG. 9 to FIG. 14, the package structure further includes a second molding layer 116 encapsulating the first chip 301, the metal wires 308, and the wire bonding pads 303.

In some embodiments, referring to FIG. 15, a plurality of external pads 302 are arranged on the functional face of the first chip 301; and the first chip 301 further includes: third heat sinks 205 that protrude from a surface of the functional face and are electrically connected to a portion of the external pads 302; fifth metal bumps 105 disposed on the first surfaces of the second interconnect metal traces 107; a plurality of sixth metal bumps 126, wherein the sixth metal bumps 126 are respectively mounted on top surfaces of the second metal bumps 102 and the fifth metal bumps 105, and the first molding layer 106 further covers sidewall surfaces of the sixth metal bumps 126 and exposes the top surfaces of the sixth metal bumps 126; and solder balls 127 disposed on the top surfaces of the sixth metal bumps 126.

Some embodiments of the present disclosure provide a method for forming a package structure. The method includes:
providing a metal foil, wherein the metal foil includes a first surface and a second surface that are opposite;
forming a plurality of first surface metal bumps and first interconnect metal traces on the first surface of the metal foil;
mounting a plurality of passive devices on top surfaces of the first surface metal bumps, wherein the passive devices are correspondingly electrically connected to the first surface metal bumps and the first interconnect metal traces;
forming a first molding layer, wherein the first molding layer encapsulates the passive devices, the first surface metal bumps, and the first interconnect metal traces, and covers the first surface of the metal foil;
etching the metal foil from the second surface of the metal foil to form second interconnect metal traces and bonding pads that are correspondingly electrically connected to the first surface metal bumps and the first interconnect metal traces;
forming a dielectric layer covering the second interconnect metal traces and a bottom surface of the first molding layer, wherein openings exposing surfaces of the bonding pads are defined in the dielectric layer;
providing a first chip, wherein the first chip includes a back face and a functional face that are opposite, wire bonding pads being arranged on the functional face;
mounting the back face of the first chip on a surface of the dielectric layer; and
forming metal wires electrically connecting the wire bonding pads to the bonding pads.

In some embodiments, a portion of the first surface metal bumps are discrete, and a portion of the first surface metal bumps are connected via the first interconnect metal traces; and the method further includes: providing a carrier plate, wherein the metal foil is disposed on a surface of the carrier plate; and removing the carrier plate prior to etching the second surface of the metal foil or after forming the first molding layer.

In some embodiments, the method further includes: forming a plurality of discrete second metal bumps on the first surface of the metal foil, wherein the second metal bumps are disposed outside the first surface metal bumps, the bonding pads are formed on bottom surfaces of the second metal bumps, and the bonding pads are correspondingly electrically connected to the first surface metal bumps and the first interconnect metal traces via a portion of the second interconnect metal traces; wherein the first molding layer further at least covers sidewall surfaces of the second metal bumps and the first interconnect metal traces.

In some embodiments, the bonding pads are formed on bottom surfaces of a portion of the first surface metal bumps.

In some embodiments, the method further includes: forming a third metal bump on the first surface of the metal foil, wherein a portion of the second interconnect metal traces formed upon etching the metal foil are electrically connected to the third metal bump; and providing a first heat sink, wherein the first heat sink is mounted on a top surface of the third metal bump; wherein the first molding layer further covers a sidewall surface of the third metal bump and at least covers a sidewall surface of the first heat sink.

In some embodiments, the third metal bump is disposed between the first surface metal bumps, and is opposite to a mount position of the first chip.

In some embodiments, in a case that a plurality of discrete second metal bumps are formed on the first surface of the metal foil, the method further includes: providing second heat sinks, wherein the second heat sinks are mounted on top surfaces of the second metal bumps; wherein the first molding layer at least further covers sidewall surfaces of the second heat sinks.

In some embodiments, the method further includes: forming a plurality of discrete fourth metal bumps on the first surface of the metal foil, wherein a portion of the second interconnect metal traces formed upon etching the metal foil are electrically connected to the fourth metal bumps; and providing a second chip, wherein the second chip is flip-mounted on top surfaces of the fourth metal bumps, and the second chip is electrically connected to the fourth metal bumps; wherein the first molding layer further covers sidewall surfaces of the fourth metal bumps and a surface of the second chip.

In some embodiments, a plurality of external pads are arranged on the functional face of the first chip; and the first chip further includes external protrusions that protrude from a surface of the functional face and are electrically connected to the external pads.

In some embodiments, the external protrusions are electrically bonded to a portion of the external pads, or the external protrusions are electrically connected to the external pads via redistribution layers.

In some embodiments, a portion of the external pads are directly used as the wire bonding pads, or a portion of the redistribution layers are used as the wire bonding pads.

In some embodiments, the method further includes: forming a second molding layer, wherein the second molding layer encapsulates the first chip, the metal wires, and the wire bonding pads.

In some embodiments, the external protrusions are solder balls or metal core balls, or the external protrusions include metal pillars and solder balls disposed on top surfaces of the metal pillars.

In some embodiments, a plurality of external pads are arranged on the functional face of the first chip; the first chip further includes third heat sinks that protrude from a surface of the functional face and are electrically connected to a portion of the external pads; and the method further includes: forming a plurality of discrete fifth metal bumps on the first surface of the metal foil, wherein a portion of the metal traces formed upon etching the metal foil are electrically connected to the fifth metal bumps; providing a plurality of sixth metal bumps, wherein the sixth metal bumps are respectively mounted on top surfaces of the second metal bumps and the fifth metal bumps, and the first molding layer further covers sidewall surfaces of the sixth metal bumps and exposes top surfaces of the sixth metal bumps; and forming solder balls on the top surfaces of the sixth metal bumps.

Some embodiments of the present disclosure further provide a package structure. The package structure includes:
a plurality of second interconnect metal traces and bonding pads in a same plane, wherein the bonding pads are electrically connected to a portion of the second interconnect metal traces, and the second interconnect metal traces and the bonding pads include first surfaces and second surfaces that are opposite;
a plurality of discrete first surface metal bumps and first interconnect metal traces disposed on the first surfaces of the second interconnect metal traces;
a plurality of passive devices correspondingly mounted on top surfaces of the first surface metal bumps, wherein the passive devices are correspondingly electrically connected to the first surface metal bumps and the first interconnect metal traces;
a first molding layer encapsulating the passive devices, the first surface metal bumps, and the first interconnect metal traces, and covering the first surfaces of the bonding pads;
a dielectric layer covering the second surfaces of the second interconnect metal traces and a bottom surface of the first molding layer, wherein openings exposing the second surfaces of the bonding pads are defined in the dielectric layer;
a first chip, wherein the first chip includes a back face and a functional face that are opposite, wire bonding pads being arranged on the functional face of the first chip, the back face of the first chip being mounted on a surface of the dielectric layer; and
metal wires electrically connecting the wire bonding pads to the second surfaces of the bonding pads.

In some embodiments, the bonding pads are disposed outside the first surface metal bumps; and the package structure further includes: a plurality of second metal bumps on the first surfaces of the bonding pads, wherein the second metal bumps are disposed outside the first surface metal bumps, the bonding pads are correspondingly electrically connected to the first surface metal bumps and the first interconnect metal traces via a portion of the second interconnect metal traces, and the first molding layer at least further covers sidewall surfaces of the second metal bumps.

In some embodiments, the bonding pads are disposed on bottom surfaces of a portion of the first surface metal bumps.

In some embodiments, the package structure further includes: a third metal bump disposed on the first surfaces of a portion of the second interconnect metal traces; and a first heat sink, wherein the first heat sink is mounted on a top surface of the third metal bump, and the first molding layer further covers a sidewall surface of the third metal bump and at least covers a sidewall surface of the first heat sink.

In some embodiments, the third metal bump is disposed between the first surface metal bumps, and is opposite to a mount position of the first chip.

In some embodiments, in a case that second metal bumps are formed on the first surfaces of the bonding pads, the package structure further includes second heat sinks, wherein the second heat sinks are mounted on top surfaces of the second metal bumps, and the first molding layer at least further covers sidewall surfaces of the second heat sinks.

In some embodiments, the package structure further includes: a plurality of discrete fourth metal bumps disposed on the first surfaces of the second interconnect metal traces; and a second chip, wherein the second chip is flip-mounted on top surfaces of the fourth metal bumps, and the second chip is electrically connected to the fourth metal bumps; wherein the first molding layer further covers sidewall surfaces of the fourth metal bumps and a surface of the second chip.

In some embodiments, a plurality of external pads are arranged on the functional face of the first chip; and the first chip further includes external protrusions that protrude from a surface of the functional face and are electrically connected to the external pads.

In some embodiments, the external protrusions are electrically bonded to a portion of the external pads, or the external protrusions are electrically connected to the external pads via redistribution layers.

In some embodiments, a portion of the external pads are directly used as the wire bonding pads, or a portion of the redistribution layers are used as the wire bonding pads.

In some embodiments, the package structure further includes a second molding layer encapsulating the first chip, the metal wires, and the wire bonding pads.

In some embodiments, the external protrusions are solder balls or metal core balls, or the external protrusions include metal pillars and solder balls disposed on top surfaces of the metal pillars.

In some embodiments, a plurality of external pads are arranged on the functional face of the first chip; and the first chip further includes: third heat sinks that protrude from a surface of the functional face and are electrically connected to a portion of the external pads; fifth metal bumps disposed on the first surfaces of the second interconnect metal traces; a plurality of sixth metal bumps, wherein the sixth metal bumps are respectively mounted on top surfaces of the second metal bumps and the fifth metal bumps, and the first molding layer further covers sidewall surfaces of the sixth metal bumps and exposes the top surfaces of the sixth metal bumps; and solder balls disposed on the top surfaces of the sixth metal bumps.

In some embodiments, a portion of the first surface metal bumps are discrete, and a portion of the first surface metal bumps are connected via the first interconnect metal traces.

In the package structure and the method for forming the same according to the embodiments of the present disclosure, a metal foil is provided, wherein the metal foil includes a first surface and a second surface that are opposite; a plurality of first surface metal bumps and first interconnect metal traces are formed on the first surface of the metal foil; a plurality of passive devices are mounted on top surfaces of the first surface metal bumps, wherein the passive devices are correspondingly electrically connected to the first surface metal bumps and the first interconnect metal traces; a first molding layer encapsulating the passive devices, the first surface metal bumps, and the first interconnect metal traces, and covering the first surface of the metal foil is formed; the metal foil is etched from the second surface of the metal foil to form second interconnect metal traces and bonding pads that are correspondingly electrically connected to the first surface metal bumps and the first interconnect metal traces; a dielectric layer covering the second interconnect metal traces and a bottom surface of the first molding layer is formed, wherein openings exposing surfaces of the bonding pads are defined in the dielectric layer; a first chip is provided, wherein the first chip comprises a back face and a functional face that are opposite, wire bonding pads being arranged on the functional face; the back face of the first chip is mounted on a surface of the dielectric layer; and metal wires electrically connecting the wire bonding pads to the bonding pads are formed. The passive devices are firstly mounted on the top surfaces of the first surface metal bumps on the first surface of the metal foil, and then the first molding layer encapsulating the passive devices, the first surface metal bumps, and the first interconnect metal traces, and covering the first surface of the metal foil is formed; the metal foil is etched from the second surface of the metal foil to form the second interconnect metal traces and the bonding pads that are correspondingly electrically connected to the first surface metal bumps; and afterwards, the back face of the first chip is mounted on the surface of the dielectric layer, and the metal wires electrically connecting the wire bonding pads to the bonding pads are formed. When mounting the passive devices, the number of passive devices in the package is increased since the passive devices are not limited by the area of the back face of the first chip. Moreover, the passive devices are electrically connected to the first chip via the metal traces and the metal wires. The formation process of the metal traces and the metal wires is simpler and less costly compared to the silicon via process.

In addition, terms “comprise,” “include,” and variations thereof used herein in the text of the present disclosure are intended to define a non-exclusive meaning. It should be noted that the terms such as “first,” “second,” and the like in the specifications, claims and the accompanying drawings of the present disclosure are intended to distinguish different objects but are not intended to define a specific order or a definite time sequence. Unless otherwise clearly indicated in the context, it should be understood that the data used in this way can be interchanged under appropriate circumstances. In cases of no conflict, the embodiments and features in the embodiments of the present disclosure may be combined together. Further, in the above description, descriptions of well-known components and techniques are omitted so as not to unnecessarily obscure the inventive concepts of the present disclosure. In various embodiments of the present disclosure, the same or similar parts between the embodiments may be referenced to each other. In each embodiment, the portion that is different from other embodiments is concentrated and described.

Although the present disclosure has been disclosed above with reference to preferred embodiments, these embodiments are not intended to limit the present disclosure but illustrate the present disclosure. Without departing from the spirit and scope of the present disclosure, any person skilled in the art may make possible variations and modifications to the technical solutions based on the method and technical content disclosed herein in this literature. Therefore, any content without departing from the technical solutions of the present disclosure and any simple variation, equivalent replacement and modification made based on the technical essence of the present disclosure shall fall within the protection scope defined by the technical solutions of the present disclosure.

What is claimed is:

1. A package structure, comprising:
a plurality of second interconnect metal traces and bonding pads in a same plane, wherein the bonding pads are electrically connected to a portion of the plurality of second interconnect metal traces, and the plurality of second interconnect metal traces and the bonding pads comprise first surfaces and second surfaces that are opposite;
a plurality of first surface metal bumps and first interconnect metal traces disposed on the first surfaces of the plurality of second interconnect metal traces;
a plurality of passive devices correspondingly mounted on top surfaces of the plurality of first surface metal bumps, wherein the plurality of passive devices are correspondingly electrically connected to the first surface metal bumps and the first interconnect metal traces;
a first molding layer encapsulating the plurality of passive devices, the plurality of first surface metal bumps, and the first interconnect metal traces, and covering the first surfaces of the bonding pads;
a dielectric layer covering the second surfaces of the second interconnect metal traces and a bottom surface of the first molding layer, wherein openings exposing the second surfaces of the bonding pads are defined in the dielectric layer;
a first chip comprising a back face and a functional face that are opposite, wherein second bonding pads are arranged on the functional face of the first chip, and the back face of the first chip is mounted on a surface of the dielectric layer; and
metal wires electrically connecting the second bonding pads to the second surfaces of the bonding pads.

2. The package structure according to claim 1, wherein the bonding pads are disposed outside the plurality of first surface metal bumps; and the package structure further comprises a plurality of second metal bumps on the first surfaces of the bonding pads, wherein the plurality of second metal bumps are disposed outside the plurality of first surface metal bumps, the bonding pads are correspondingly electrically connected to the plurality of first surface metal bumps and the first interconnect metal traces via a portion of the plurality of second interconnect metal traces, and the first molding layer at least further covers sidewall surfaces of the plurality of second metal bumps.

3. The package structure according to claim 1, wherein the bonding pads are disposed on bottom surfaces of a portion of the plurality of first surface metal bumps.

4. The package structure according to claim 1, further comprising: a third metal bump disposed on the first surfaces of a portion of the plurality of second interconnect metal traces; and a first heat sink, wherein the first heat sink is mounted on a top surface of the third metal bump, and the first molding layer further covers a sidewall surface of the third metal bump and at least covers sidewall surfaces of the first heat sink.

5. The package structure according to claim 4, wherein the third metal bump is disposed between the plurality of first surface metal bumps, and is opposite to a mount position of the first chip.

6. The package structure according to claim 4, wherein in a case that plurality of second metal bumps are formed on the first surfaces of the bonding pads, the package structure further comprises second heat sinks, wherein the second heat sinks are mounted on top surfaces of the plurality of second metal bumps, and the first molding layer at least further covers sidewall surfaces of the second heat sinks.

7. The package structure according to claim 1, further comprising: a plurality of discrete fourth metal bumps disposed on the first surfaces of the plurality of second interconnect metal traces; and a second chip, wherein the second chip is flip-mounted on top surfaces of the fourth metal bumps, and the second chip is electrically connected to the fourth metal bumps; wherein the first molding layer further covers sidewall surfaces of the fourth metal bumps and surfaces of the second chip.

8. The package structure according to claim 1, wherein a plurality of external pads are arranged on the functional face of the first chip; and the first chip further comprises external protrusions that protrude from a surface of the functional face and are electrically connected to a portion of the plurality of external pads.

9. The package structure according to claim 8, wherein the external protrusions are electrically bonded to a portion of the plurality of external pads, or the external protrusions are electrically connected to a portion of the plurality of external pads via redistribution layers.

10. The package structure according to claim 9, wherein a portion of the plurality of external pads are directly used as the second bonding pads, or a portion of the redistribution layers are used as the second bonding pads.

11. The package structure according to claim 9, further comprising: a second molding layer encapsulating the first chip, the metal wires, and the second bonding pads.

12. The package structure according to claim 9, wherein the external protrusions are solder balls or metal core balls, or the external protrusions comprise metal pillars and solder balls disposed on top surfaces of the metal pillars.

13. The package structure according to claim 1, wherein a plurality of external pads are arranged on the functional face of the first chip; and the first chip further comprises: third heat sinks that protrude from a surface of the functional face and are electrically connected to a portion of the plurality of external pads; fifth metal bumps disposed on the first surfaces of the plurality of second interconnect metal traces; a plurality of sixth metal bumps, wherein the plurality of sixth metal bumps are respectively mounted on top surfaces of plurality of second metal bumps and the fifth metal bumps, and the first molding layer further covers sidewall surfaces of the plurality of sixth metal bumps and exposes top surfaces of the plurality of sixth metal bumps; and solder balls disposed on the top surfaces of the plurality of sixth metal bumps.

14. The package structure according to claim 1, wherein a portion of the plurality of first surface metal bumps are discrete, and a portion of the plurality of first surface metal bumps are connected via the first interconnect metal traces.

15. A method for forming a package structure, comprising:
providing a metal foil, wherein the metal foil comprises a first surface and a second surface that are opposite;
forming a plurality of first surface metal bumps and first interconnect metal traces on the first surface of the metal foil;
mounting a plurality of passive devices on top surfaces of the plurality of first surface metal bumps, wherein the plurality of passive devices are correspondingly electrically connected to the plurality of first surface metal bumps and the first interconnect metal traces;
forming a first molding layer, wherein the first molding layer encapsulates the plurality of passive devices, the plurality of first surface metal bumps, and the first interconnect metal traces, and covers the first surface of the metal foil;
etching the metal foil from the second surface of the metal foil to form a plurality of second interconnect metal traces and bonding pads that are correspondingly electrically connected to the plurality of first surface metal bumps and the first interconnect metal traces;
forming a dielectric layer covering the plurality of second interconnect metal traces and a bottom surface of the first molding layer, wherein openings exposing surfaces of the bonding pads are defined in the dielectric layer;
providing a first chip, wherein the first chip comprises a back face and a functional face that are opposite, second bonding pads being arranged on the functional face;
mounting the back face of the first chip on a surface of the dielectric layer; and
forming metal wires electrically connecting the second bonding pads to the bonding pads.

16. The method according to claim 15, wherein a portion of the plurality of first surface metal bumps are discrete, and a portion of the plurality of first surface metal bumps are connected via the first interconnect metal traces; and the method further comprises: providing a carrier plate, wherein the metal foil is disposed on a surface of the carrier plate; and removing the carrier plate prior to etching the second surface of the metal foil or after forming the first molding layer.

17. The method according to claim 15, further comprising: forming a plurality of discrete second metal bumps on the first surface of the metal foil, wherein the plurality of discrete second metal bumps are disposed outside the plurality of first surface metal bumps, the bonding pads are formed on bottom surfaces of the plurality of discrete second metal bumps, and the bonding pads are correspondingly electrically connected to the plurality of first surface metal bumps and the first interconnect metal traces via a portion of the plurality of second interconnect metal traces; wherein the first molding layer further at least covers sidewall surfaces of the plurality of discrete second metal bumps and the first interconnect metal traces.

18. The method according to claim 15, further comprising: forming a third metal bump on the first surface of the metal foil, wherein a portion of the plurality of second interconnect metal traces formed upon etching the metal foil are electrically connected to the third metal bump; and providing a first heat sink, wherein the first heat sink is mounted on a top surface of the third metal bump; wherein the first molding layer further covers sidewall surfaces of the third metal bump and at least covers sidewall surfaces of the first heat sink.

19. The method according to claim 18, wherein in a case that a plurality of discrete second metal bumps are formed on the first surface of the metal foil, the method further comprises: providing second heat sinks, wherein the second heat sinks are mounted on top surfaces of the plurality of discrete second metal bumps; wherein the first molding layer at least further covers sidewall surfaces of the second heat sinks.

20. The method according to claim 17, wherein a plurality of external pads are arranged on the functional face of the first chip; the first chip further comprises third heat sinks that protrude from a surface of the functional face and are electrically connected to a portion of the plurality of external pads; and the method further comprises: forming a plurality of discrete fifth metal bumps on the first surface of the metal foil, wherein a portion of the metal traces formed upon etching the metal foil are electrically connected to the fifth metal bumps; providing a plurality of sixth metal bumps, wherein the plurality of sixth metal bumps are respectively mounted on top surfaces of the plurality of discrete second metal bumps and the fifth metal bumps, and the first molding layer further covers sidewall surfaces of the plurality of sixth metal bumps and exposes top surfaces of the plurality of sixth metal bumps; and forming solder balls on the top surfaces of the plurality of sixth metal bumps.
